(19) United States
(12) Patent Application Publication
(10) Pub. No.: US 2025/0098486 A1
(43) Pub. Date: Mar. 20, 2025

(54) Color Film Substrate, Display Panel and Display Apparatus

(71) Applicant: BOE Technology Group Co., Ltd., Beijing (CN)

(72) Inventors: Dejiang ZHAO, Beijing (CN); Xue JIANG, Beijing (CN)

(21) Appl. No.: 18/578,022

(22) PCT Filed: Aug. 26, 2022
(86) PCT No.: PCT/CN2022/115227

§ 371 Date: Jan. 10, 2024

(51) Int. Cl. H10K 59/80; H10K 59/122; H10K 59/38

(52) U.S. Cl. CPC H10K 59/873; H10K 59/122; H10K 59/38

(57) ABSTRACT

A color film substrate, a display panel and a display apparatus are provided. The color film substrate includes: a first base substrate including display sub-pixel regions and dummy sub-pixel regions; a first pixel definition layer including first opening regions one-to-one corresponding to the display sub-pixel regions and second opening regions one-to-one corresponding to the dummy sub-pixel regions; a plurality of photoluminescence layers within at least part of the first opening regions; a first encapsulation layer on a side of the first pixel definition layer and the photoluminescence layers facing away from the first base substrate; a plurality of support portions on a side of the first encapsulation layer facing away from the first base substrate; an orthographic projection of the support portions on the first base substrate is not overlapped with an orthographic projection of the first opening regions on the first base substrate.

### CROSS-REFERENCE TO RELATED APPLICATION

The present application is a U.S. National Phase Entry of International Application PCT/CN2022/115227 having an international filing date of Aug. 26, 2022, and entitled “Color Film Substrate, Display Panel and Display Apparatus”, the contents of which are hereby incorporated herein by reference in their entireties.

### TECHNICAL FIELD

The present disclosure relates to the field of display technologies, and particularly to a color film substrate, a display panel and a display apparatus.

### BACKGROUND

Quantum Dots (QD) have attracted much attention and research in recent years because of their wide color gamut and high efficiency. At present, a quantum dot technology used in display products is photoluminescence quantum dot technology.

At present, a mature QD technology is QD-Organic Light Emitting Diode (OLED) technology. One of the processes for making QD-OLED is a cell alignment process for QD substrate and OLED substrate, which requires coating a thick filler between a QD substrate and an OLED substrate. The thick filler leads to a long distance between QD and OLED, which is prone to cross-color.

### SUMMARY

An embodiment of the present disclosure provides a color film substrate, which includes:
a first base substrate including a plurality of display sub-pixel regions and a plurality of dummy sub-pixel regions arranged in an array;
a first pixel definition layer located on a side of the first base substrate and including a plurality of first opening regions and a plurality of second opening regions; the first opening regions are in one-to-one correspondence with the display sub-pixel regions, and the second opening regions are in one-to-one correspondence with the dummy sub-pixel regions;
a plurality of photoluminescence layers located within at least a part of the first opening regions;
a first encapsulation layer located on a side of the first pixel definition layer and the photoluminescence layers facing away from the first base substrate; an orthographic projection of the first encapsulation layer on the first base substrate covers orthographic projections of the first pixel definition layer, the photoluminescence layers, the first opening regions and the second opening regions on the first base substrate; and
a plurality of support portions located on a side of the first encapsulation layer facing away from the first base substrate; an orthographic projection of the support portions on the first base substrate is not overlapped with an orthographic projection of the first opening regions on the first base substrate; and a distance between a surface of each support portion facing away from the first base substrate and the first base substrate is greater than a maximum value of a distance between a surface of the first encapsulation layer facing away from the first base substrate and the first base substrate.

In some embodiments, a ratio of a quantity of display sub-pixel regions to a quantity of dummy sub-pixel regions is a positive integer;
the plurality of display sub-pixel regions and the plurality of dummy sub-pixel regions are arranged in an array along a first direction and a second direction, wherein the first direction intersects with the second direction;

In the first direction and/or in the second direction, a quantity of display sub-pixel region(s) spaced between any two adjacent dummy sub-pixel regions is the same.

In some embodiments, a shape of an orthographic projection of a first opening region on the first base substrate is the same as a shape of an orthographic projection of a second opening region on the first base substrate, and an area of the orthographic projection of the first opening region on the first base substrate is substantially equal to an area of the orthographic projection of the second opening region on the first base substrate.

In some embodiments, the plurality of display sub-pixel regions and the plurality of dummy sub-pixel regions are divided into a plurality of pixel regions; and each of the pixel regions includes a plurality of the display sub-pixel regions and one of the dummy sub-pixel regions.

In some embodiments, each of the pixel regions includes three display sub-pixel regions and one dummy sub-pixel region, and the three display sub-pixel regions and the one dummy sub-pixel region are arranged in a 2×2 array.

In some embodiments, an area of an orthographic projection of a support portion on the first base substrate is smaller than an area of an orthographic projection of a second opening region on the first base substrate, and the orthographic projection of the support portion on the first base substrate falls within the orthographic projection of the second opening region on the first base substrate.

In some embodiments, a center of the orthographic projection of the support portion on the first base substrate substantially coincides with a center of the orthographic projection of the second opening region on the first base substrate.

In some embodiments, a quantity of the support portions is the same as a quantity of the second opening regions.

In some embodiments, the orthographic projection of the support portions on the first base substrate falls within the orthographic projection of the first pixel definition layer on the first base substrate.

In some embodiments, orthographic projections of a plurality of support portions on the first base substrate surround an orthographic projection of a second opening region on the first base substrate.

In some embodiments, in a direction from the first base substrate towards the support portions, an area of a cross section of each support portion parallel to the first base substrate is gradually reduced.

In some embodiments, a ratio of an area of the surface of the support portion facing away from the first base substrate to an area of a surface of the support portion close to the first base substrate is greater than or equal to 0.6 and less than 1.

In some embodiments, an orthographic projection of the support portion on the first base substrate is circular.

In some embodiments, a diameter of the surface of the support portion facing away from the first base substrate is greater than or equal to 3 microns and less than or equal to 10 microns.

In some embodiments, the distance h1 between the surface of the support portion facing away from the first base substrate and the first base substrate, and the maximum value h2 of the distance between the surface of the first encapsulation layer facing away from the first base substrate and the first base substrate satisfy: 1 micron≥h1−h2≥3 microns.

In some embodiments, the color film substrate further includes:
a first light shielding layer, located between the first pixel definition layer and the first base substrate and including a plurality of third opening regions and a plurality of fourth opening regions; the third opening regions are in one-to-one correspondence with the display sub-pixel regions, and the fourth opening regions are in one-to-one correspondence with the dummy sub-pixel regions; and
a plurality of color resists, located within the third opening regions.

In some embodiments, the color film substrate further includes:
a first lyophobic layer located between the color resists and the photoluminescence layers.

An embodiment of the present disclosure provides a display panel, which includes:
an array substrate;
a color film substrate provided by an embodiment of the present disclosure and arranged opposite to the array substrate; the support portions are in contact with the array substrate;
a filling portion located between the array substrate and the color film substrate; and the filling portion is partially filled in regions corresponding to the second opening regions.

In some embodiments, the array substrate includes:
a second base substrate;
a plurality of light emitting devices which are located on a side of the second base substrate facing the color film substrate and are in one-to-one correspondence with the display sub-pixel regions;
a second encapsulation layer located on a side of the light emitting devices facing the color film substrate and including an organic encapsulation structure; the organic encapsulation structure includes a plurality of protrusion portions, and a surface of each protrusion portion facing away from the second base substrate is a spherical surface or an ellipsoidal surface; the protrusion portions are in one-to-one correspondence with the light emitting devices, and an orthographic projection of the protrusion portions on the second base substrate covers an orthographic projection of the light emitting devices on the second base substrate.

In some embodiments, the organic encapsulation structure further includes an organic lyophobic layer;
the organic lyophobic layer is arranged as a whole layer between the organic encapsulation structure and the second base substrate; or the organic lyophobic layer includes a plurality of fifth opening regions, and the protrusion portions are located within the fifth opening regions.

An embodiment of the present disclosure provides a display apparatus, including a display panel provided by an embodiment of the present disclosure.

### BRIEF DESCRIPTION OF DRAWINGS

In order to describe technical solutions in embodiments of the present disclosure more clearly, the drawings to be used in describing the embodiments will be introduced below in brief. Apparently, the drawings described below are only some of the embodiments of the present disclosure, and those of ordinary skills in the art may also obtain other drawings according to these drawings without using any inventive effort.

FIG. 1 is a schematic view of a color film substrate according to an embodiment of the present disclosure.

FIG. 2 is a cross-sectional view along AA′ in FIG. 1 according to an embodiment of the present disclosure.

FIG. 3 is a schematic view of a structure of another color film substrate according to an embodiment of the present disclosure.

FIG. 4 is a schematic view of a relationship between an orthographic projection of a second opening region and an orthographic projection of a support portion in a color film substrate according to an embodiment of the present disclosure.

FIG. 5 is a schematic view of a relationship between an orthographic projection of a second opening region and an orthographic projection of a support portion in another color film substrate according to an embodiment of the present disclosure.

FIG. 6 is a cross-sectional view along BB′ in FIG. 5 according to an embodiment of the present disclosure.

FIG. 7 is a schematic view of a structure of another color film substrate according to an embodiment of the present disclosure.

FIG. 8 is a schematic view of a structure of another a color film substrate according to an embodiment of the present disclosure.

FIG. 9 is a top view of a support structure according to an embodiment of the present disclosure.

FIG. 10 is a schematic view of a structure of another color film substrate according to an embodiment of the present disclosure.

FIG. 11 is a schematic view of a structure of another color film substrate according to an embodiment of the present disclosure.

FIG. 12 is a schematic view of a structure of a display panel according to an embodiment of the present disclosure.

FIG. 13 is a schematic diagram of a structure of a drive circuit layer according to an embodiment of the present disclosure.

### DETAILED DESCRIPTION

In order to make objectives, technical solutions and advantages of the embodiments of the present disclosure more clear, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Furthermore, embodiments in the present disclosure and features in the embodiments may be combined with each other if there is no conflict. Based on the described embodiments of the present disclosure, all other embodiments obtained by those of ordinary skills in the art without inventive effort shall fall within the protection scope of the present disclosure.

Unless otherwise defined, technical terms or scientific terms used in the present disclosure should have common meanings as understood by those of ordinary skills in the art that the present disclosure pertains to. “First”, “second”, and similar wordings used in the present disclosure do not indicate any order, quantity, or importance, but are used only for distinguishing different components. “Include”, “contain”, or a similar wording mean that elements or objects appearing before the wording cover elements or objects listed after the wording and equivalents thereof, but do not exclude other elements or objects. “Connect”, “join”, or a similar wording is not limited to a physical or mechanical connection, but may include an electrical connection, whether direct or indirect.

It should be noted that sizes and shapes of figures in the drawings do not reflect actual scales, and are only for the purpose of schematically illustrating contents of the present disclosure. Moreover, same or similar elements and elements having same or similar functions are denoted by same or similar reference numerals throughout the descriptions.

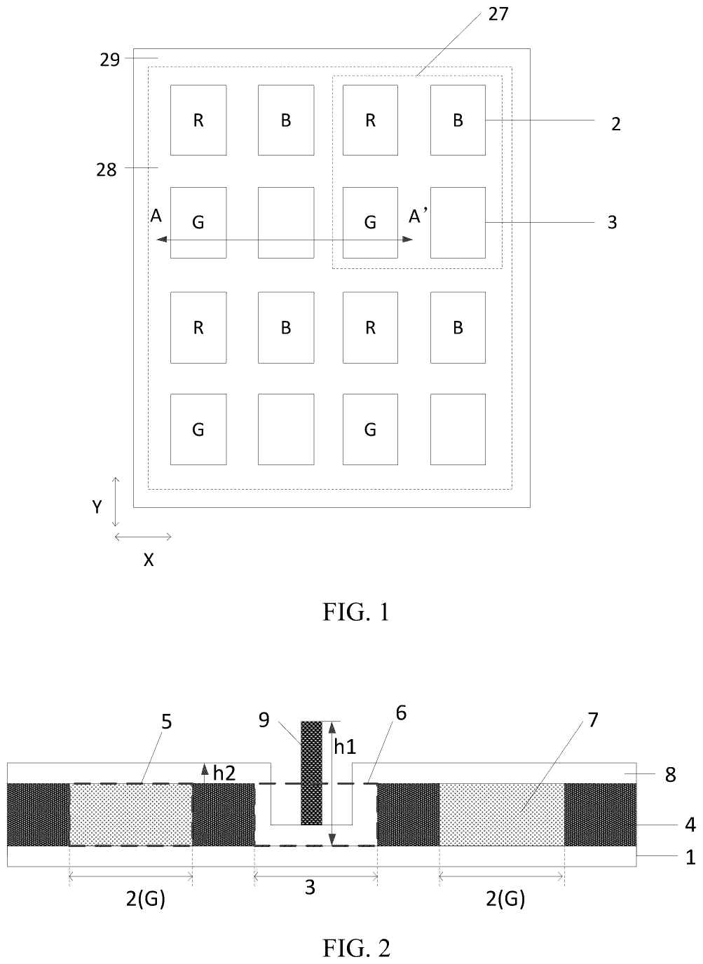

An embodiment of the present disclosure provides a color film substrate, as shown in FIG. 1 and FIG. 2, and the color film substrate includes:
a first base substrate 1 including a plurality of display sub-pixel regions 2 and a plurality of dummy sub-pixel regions 3 arranged in an array;
a first pixel definition layer 4 located on a side of the first base substrate 1 and including a plurality of first opening regions 5 and a plurality of second opening regions 6; the first opening regions 5 are in one-to-one correspondence with the display sub-pixel regions 2, and the second opening regions 6 are in one-to-one correspondence with the dummy sub-pixel regions 3;
a plurality of photoluminescence layers 7 located in at least a part of the first opening regions 5;
a first encapsulation layer 8 located on a side of the first pixel definition layer 4 and the photoluminescence layers 7 facing away from the first base substrate 1; an orthographic projection of the first encapsulation layer 8 on the first base substrate 1 covers orthographic projections of the first pixel definition layer 4, the photoluminescence layers 7, the first opening regions 5 and the second opening regions 6 on the first base substrate 1; and
a plurality of support portions 9 located on a side of the first encapsulation layer 8 facing away from the first base substrate 1; an orthographic projection of the support portions 9 on the first base substrate 1 is not overlapped with an orthographic projection of the first opening regions 5 on the first base substrate 1; and a distance between a surface of the support portions 9 facing away from the first base substrate 1 and the first base substrate 1 is greater than a maximum value of a distance between a surface of the first encapsulation layer 8 facing away from the first base substrate 1 and the first base substrate 1.

It should be noted that the color film substrate according to the embodiment of the present disclosure may be applied to a display panel. The display panel further includes an array substrate arranged opposite to the color film substrate, the array substrate includes a plurality of light emitting devices, and the photoluminescence layers are used for absorbing light emitted by the light emitting devices to radiate light of a desired color. One of the manufacturing processes of the display panel is that the color film substrate and the array substrate form the display panel through a cell alignment process, and a filler needs to be arranged between the color film substrate and the array substrate to form a filling portion.

The color film substrate according to the embodiment of the present disclosure includes a plurality of support portions, and the support portions are arranged in a region outside the first opening regions, so that the displaying will not be affected. Since the distance between the surface of the support portions facing away from the first base substrate and the first base substrate is larger than the maximum value of the distance between the surface of the first encapsulation layer facing away from the first base substrate and the first base substrate, the support portions may play a supporting role in the cell alignment process when the a display panel needs to be formed by the color film and the array substrate through the cell alignment process, so even if a thickness of the filler between the color film substrate and the array substrate used in the cell alignment process is reduced, a supporting strength of the cell alignment process can be ensured and a thickness uniformity of the display panel obtained after the cell alignment process can be ensured. Moreover, since the color film substrate is provided with the dummy sub-pixel regions, and the first pixel definition layer includes the second opening regions corresponding to the dummy sub-pixel regions, regions corresponding to the second opening regions do not need to perform displaying, so that no photoluminescence layer needs to be provided. Therefore, the first encapsulation layer covers the second opening regions to form grooves. In the cell alignment process, the color film substrate and the array substrate are pressed, and excess filler may be squeezed to the region corresponding to the second opening regions and be stored, which may further reduce a minimum thickness of a filling portion formed by the filler between the color film substrate and the array substrate. Under the condition that the minimum thickness of the filling portion between the color film substrate and the array substrate is reduced, a distance between each photoluminescence layer and a light emitting device in the array substrate is also reduced accordingly, thus avoiding cross-color between adjacent photoluminescence layers.

It should be noted that for example, FIG. 2 is a cross-sectional view along AA′ in FIG. 1.

As shown in FIG. 1, the color film substrate includes a display area 28 and a peripheral area 29 outside the display area 28. The display sub-pixel regions 2 and the dummy sub-pixel regions 3 are both located in the display area 28.

In a specific implementation, the first pixel definition layer is used for defining a light emitting region of the display sub-pixels and regions corresponding to the dummy sub-pixel regions. The first pixel definition layer may include a light shielding material so that light emitted from the photoluminescence layers can be prevented from passing through the first pixel definition layer to other display sub-pixel regions. In a direction perpendicular to the first base substrate, a thickness of the first pixel definition layer is, for example, greater than or equal to 3 microns and less than or equal to 15 microns. Since the photoluminescence layers are arranged in the first opening regions, a thickness of each photoluminescence layer is less than or equal to the thickness of the first pixel definition layer in the direction perpendicular to the first base substrate.

In a specific implementation, the first encapsulation layer is used for blocking water and oxygen, so that the photoluminescence layers can be prevented from being eroded by water and oxygen. The material of the first encapsulation layer includes, for example, silicon nitride or silicon oxide, and a thickness of the first encapsulation layer is, for example, greater than or equal to 0.1 micron and less than or equal to 1 micron.

In some embodiments, the photoluminescence layers are a quantum dot photoluminescence layers, i.e. a material of the photoluminescence layers includes quantum dots.

In some embodiments, as shown in FIG. 1, a ratio of the quantity of the display sub-pixel regions 2 to the quantity of the dummy sub-pixel regions 3 is a positive integer.

A plurality of display sub-pixel regions 2 and a plurality of dummy sub-pixel regions 3 are arranged in an array along a first direction X and a second direction Y, and the first direction X intersects with the second direction Y.

In the first direction X and/or in the second direction Y, the quantity of display sub-pixel region(s) 2 provided between any two adjacent dummy sub-pixel regions 3 is the same.

In the color film substrate according to the embodiment of the present disclosure, the ratio of the quantity of the display sub-pixel regions to the quantity of the dummy sub-pixel regions is a positive integer, and in the first direction and/or in the second direction, the quantity of display sub-pixel region(s) provided between any two adjacent dummy sub-pixel regions is the same, i.e. the dummy sub-pixel regions are uniformly distributed between the display sub-pixel regions, and the dummy sub-pixel regions are uniformly distributed in the display area, which can avoid the dummy sub-pixels from affecting the display effect.

It should be noted that in FIG. 1, it is illustrated by taking that the ratio of the quantity of the display sub-pixel regions 2 to the quantity of the dummy sub-pixel regions 3 is 3 as an example. In FIG. 1, one display sub-pixel region 2 is provided between any two adjacent dummy sub-pixel regions 3. Evidently, the ratio of the quantity of the display sub-pixel regions to the quantity of the dummy sub-pixel regions and the number of display sub-pixel regions provided between any two adjacent dummy sub-pixel regions may be set according to actual needs.

In some embodiments, as shown in FIG. 1, a shape of an orthographic projection of a first opening region 5 on the first base substrate 1 is the same as a shape of an orthographic projection of a second opening region 6 on the first base substrate, and an area of the orthographic projection of the first opening region 5 on the first base substrate 1 is substantially equal to an area of the orthographic projection of the second opening region 6 on the first base substrate 1.

In some embodiments, as shown in FIG. 1, a plurality of display sub-pixel regions 2 and a plurality of dummy sub-pixel regions 3 are divided into a plurality of pixel regions 27. Each pixel region 27 includes a plurality of display sub-pixel regions 2 and one dummy sub-pixel region 3.

In the color film substrate according to the embodiment of the disclosure, each pixel region includes one dummy sub-pixel region, which can further ensure uniformity of distribution of the dummy sub-pixel regions in the display area and avoid the dummy sub-pixel from affecting the display effect.

In some embodiments, as shown in FIG. 1, each pixel region 27 includes three display sub-pixel regions 2 and one dummy sub-pixel region 3, and the three display sub-pixel regions 2 and the one dummy sub-pixel region 3 are arranged in a 2×2 array.

In some embodiments, as shown in FIG. 1, three display sub-pixel regions 2 included in each pixel region 27 are respectively a red sub-pixel region R, a blue sub-pixel region B and a green sub-pixel region G. The red sub-pixel region R and the blue sub-pixel region B are located in a same row, and the green sub-pixel region G and the dummy sub-pixel region 3 are located in another row. Evidently, the three display sub-pixel regions may be arranged in other ways, for example, the red sub-pixel region R and the green sub-pixel region G are located in a same row, or the blue sub-pixel region B and the green sub-pixel region G are located in a same row.

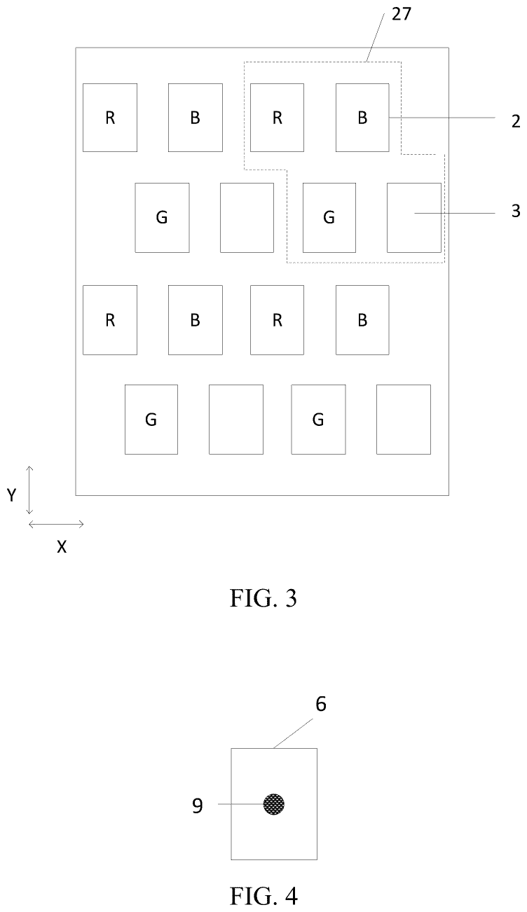

Evidently, in specific implementation, the display sub-pixel regions and the dummy sub-pixel region included in the pixel region may be in other ways. For example, as shown in FIG. 3, the display sub-pixel regions and the dummy sub-pixel region included in the pixel region are still arranged in two rows, but in each pixel region 27, the display sub-pixel regions 2 in one row and the display sub-pixel region 2 and the dummy sub-pixel region 3 in the other adjacent row are arranged in a staggered manner. Or, the display sub-pixel regions and the dummy sub-pixel region included in the pixel region may also be arranged in one row. A specific arrangement of a plurality of display sub-pixel regions in each pixel region may also be set according to actual needs, which will not be repeated here.

In some embodiments, a photoluminescence layer is arranged within each first opening. In this case, the light emitting devices in the array substrate emit white light, for example.

Optionally, in some embodiments, the photoluminescence layer is only arranged within first openings corresponding to the red display sub-pixel region and the green sub-pixel region. In this case, the light emitting devices in the array substrate are all blue light emitting devices. The photoluminescence layer includes a red light quantum dot layer arranged within the first opening region corresponding to the red display sub-pixel region and a green light quantum dot layer arranged within the first opening region corresponding to the green display sub-pixel region. The red light quantum dot layer absorbs blue light and radiates green light, and the green light quantum dot layer absorbs blue light and radiates green light. Since the light emitting devices are blue light emitting devices, no quantum dot layer needs to be arranged within the first opening regions corresponding to the blue display sub-pixel regions, which can also achieve full-color displaying of the display panel. The color film substrate further includes a light transmitting filling layer located within the first openings corresponding to the blue sub-pixel regions.

In some embodiments, as shown in FIG. 2 and FIG. 4, an area of an orthographic projection of a support portion 9 on the first base substrate 1 is smaller than an area of an orthographic projection of a second opening region 6 on the first base substrate 1, and the orthographic projection of the support portion 9 on the first base substrate 1 falls within the orthographic projection of the second opening region 6 on the first base substrate 1.

That is, the support portion is arranged within a region corresponding to the second opening region. When the color film substrate needs to be provided with a support portion, the region corresponding to the second opening region accommodates the support portion, which can reduce a design and a manufacturing difficulty of the color film substrate.

In some embodiments, as shown in FIG. 4, a center of the orthographic projection of the support portion 9 on the first base substrate 1 substantially coincides with a center of the orthographic projection of the second opening region 6 on the first base substrate 1.

It should be noted that the center of the orthographic projection of the support portion on the first base substrate substantially coincides with the center of the orthographic projection of the second opening region on the first base substrate, which means that a distance between the center of the orthographic projection of the support portion on the first base substrate and the center of the orthographic projection of the second opening region on the first base substrate is within an allowed error range. That is, when the distance between the center of the orthographic projection of the support portion on the first base substrate and the center of the orthographic projection of the second opening region on the first base substrate is within an allowed error range, the center of the orthographic projection of the support portion on the first base substrate may be considered to coincide with the center of the orthographic projection of the second opening region on the first base substrate.

In some embodiments, the quantity of support portions is the same as the quantity of second opening regions. That is, the support portions are in one-to-one correspondence with the second opening regions, and each region corresponding to the second opening region accommodates one support portion. In this way, the support portions can play a supporting role in a cell alignment process, and at the same time, the support portions can be avoided from excessively occupying an accommodating space of regions corresponding to the second opening regions.

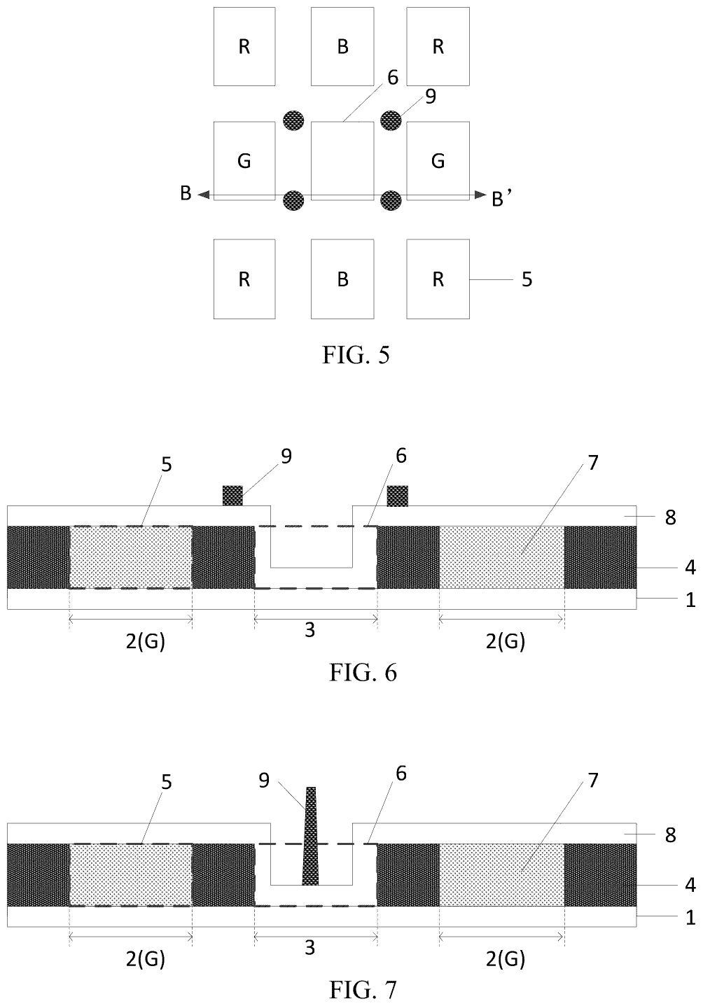

Optionally, in some embodiments, as shown in FIG. 5 and FIG. 6, an orthographic projection of the support portions 9 on the first base substrate 1 falls within an orthographic projection of the first pixel definition layer 4 on the first base substrate 1.

It should be noted that, FIG. 6 is a cross-sectional view along BB′ in FIG. 5.

In the color film substrate according to the embodiment of the present disclosure, the orthographic projection of the support portions on the first base substrate falls within the orthographic projection of the first pixel definition layer on the first base substrate, so that the support portions can play a supporting role in the cell alignment process, and at the same time the support portions can be avoided from occupying the accommodating space of the regions corresponding to the second opening regions.

In some embodiments, as shown in FIG. 5, orthographic projections of a plurality of support portions 9 on the first base substrate 1 surround an orthographic projection of the second opening region 6 on the first base substrate 1.

In FIG. 5, it is illustrated by taking that the orthographic projections of four support portions 9 on the first base substrate 1 surround the orthographic projection of the second opening region 6 on the first base substrate 1 as an example. The quantity of the support portions provided around the second opening region may be set according to actual needs.

In some embodiments, as shown in FIG. 2 and FIG. 6, in a direction from the first base substrate 1 towards the support portions 9, areas of cross sections of the support portions 9 at different positions parallel to of the first base substrate 1 are the same.

In a case that the areas of the cross sections of the support portions at different positions parallel to the first base substrate are the same, in some embodiments, as shown in FIG. 1 and FIG. 5, the orthographic projections of the support portions 9 on the first base substrate 1 are circular.

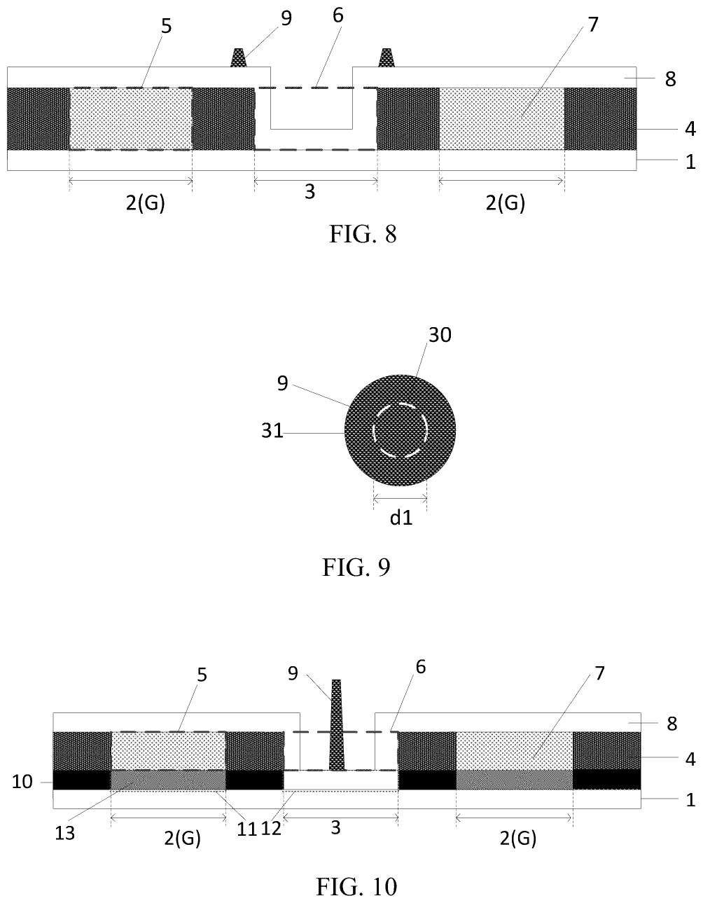

Optionally, in some embodiments, as shown in FIG. 7 and FIG. 8, in the direction from the first base substrate 1 towards a support portion 9, an area of a cross section of the support portion 9 parallel to of the first base substrate 1 is gradually reduced.

In some embodiments, as shown in FIG. 9, a ratio of an area of a surface 30 of the support portion 9 facing away from the first base substrate to an area of a surface 31 of the support portion 9 close to the first base substrate is greater than or equal to 0.6 and less than 1.

It should be noted that FIG. 9 is an orthographic projection of the support portion 9 shown in FIG. 7 and FIG. 8 on the first base substrate.

In some embodiments, as shown in FIG. 9, the orthographic projection of the support portion 9 on the first base substrate is circular.

Evidently, the shape of the orthographic projection of the support portion on the first base substrate may be another shape such as a rectangle or an ellipse.

In some embodiments, as shown in FIG. 9, a diameter d1 of the surface 30 of the support portion 9 facing away from the first base substrate 1 is greater than or equal to 3 microns and less than or equal to 10 microns.

In some embodiments, a distance h1 between the surface of the support portion facing away from the first base substrate and the first base substrate, and a maximum value h2 of a distance between a surface of the first encapsulation layer facing away from the first base substrate and the first base substrate satisfy: 1 micron≥h1−h2≥3 microns.

In the color film substrate according to the embodiment of the present disclosure, 1 micron≥h1−h2≥3 microns, the support portion is configured to play a supporting role in a cell alignment process, and at the same time, an height of the support portion in the direction perpendicular to the first base substrate is avoided from being too high, which can avoid increasing a manufacturing difficulty of the support portion and avoid falling off due to insufficient rigidity of the support portion. It is possible to avoid increasing a distance between the photoluminescence layer and the light emitting device under the condition of ensuring a supporting strength of the support portion.

In specific implementation, when the support portion is located in a region corresponding to a second opening region, h1−h2 is a height difference between the support portion and the first encapsulation layer in the direction perpendicular to the first base substrate. When an orthographic projection of the support portion on the first base substrate falls within an orthographic projection of the first pixel definition layer on the first base substrate, h1−h2 is a height of the support portion in the direction perpendicular to the first base substrate.

In some embodiments, a material of the support portion includes an epoxy resin-based material. Therefore, a supportability of the support portion can be ensured, and adhesion between the support portion and the first encapsulation layer can also be ensured.

In some embodiments, as shown in FIG. 10, the color film substrate further includes:
a first light shielding layer 10 located between the first pixel definition layer 4 and the first base substrate 1 and including a plurality of third opening regions 11 and a plurality of fourth opening regions 12; the third opening regions 12 are in one-to-one correspondence with the display sub-pixel regions 2, and the fourth opening regions 12 are in one-to-one correspondence with the dummy sub-pixel regions 3; and
a plurality of color resists 13 located within the third opening regions 11.

In the color film substrate according to the embodiment of the present disclosure, the color resists are also provided in regions corresponding to the display sub-pixel regions, which thus can improve a light emitting color purity of the color film substrate. In addition, the first light shielding layer for defining the display sub-pixel regions further includes the fourth opening regions corresponding to the dummy sub-pixel regions, and the fourth opening regions are not provided with a color resist, which can increase depths of grooves that may accommodate a filler and are formed in regions corresponding to the dummy sub-pixel regions covered by the first encapsulation layer. In this way, regions corresponding to the fourth opening regions and the second opening regions can accommodate more filler, which is beneficial for reducing a minimum thickness of the filling portion formed by the filler between the color film substrate and the array substrate, reducing a distance between the photoluminescence layers and the light emitting devices in the array substrate, and avoiding the cross-color between adjacent photoluminescence layers.

In some embodiments, an orthographic projection of the fourth opening regions on the first base substrate is overlapped with an orthographic projection of the second opening regions on the first base substrate; and an orthographic projection of the third opening regions on the first base substrate is overlapped with an orthographic projection of the first opening regions on the first base substrate.

In some embodiments, a shape of a cross section of a fourth opening region in the direction perpendicular to the first base substrate, a shape of a cross section of a third opening region in the direction perpendicular to the first base substrate, a shape of a cross section of a second opening region in the direction perpendicular to the first base substrate, and a shape of a cross section of a first opening region in the direction perpendicular to the first base substrate are all rectangular.

In specific implementation, when a plurality of display sub-pixel regions include a red sub-pixel region R, a blue sub-pixel region B, and a green sub-pixel region G, the color resists include a red color resist corresponding to the red sub-pixel region R, a blue color resist corresponding to the blue sub-pixel region B, and a green color resist corresponding to the green sub-pixel region G.

In some embodiments, thicknesses of the first light shielding layer and the color resist are greater than or equal to 1.2 microns and less than or equal to 2.5 microns.

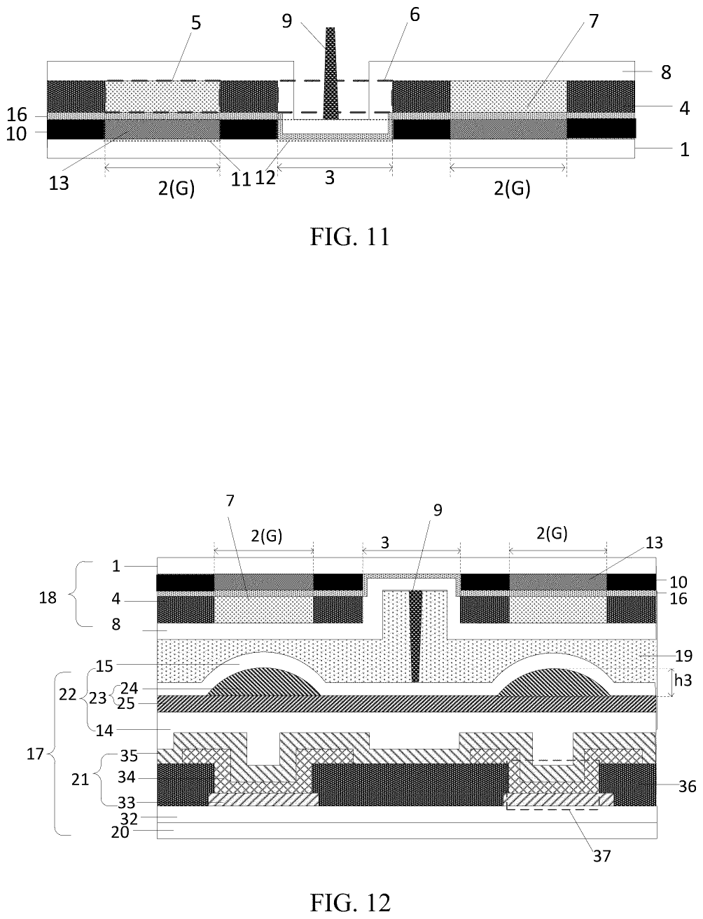

In some embodiments, as shown in FIG. 11, the color film substrate further includes:
a first lyophobic layer 16 located between the color resists 13 and the photoluminescence layers 7.

In specific implementation, before the photoluminescence layers are formed, the first lyophobic layer is formed on a side of the color resists facing away from the first base substrate, and then a quantum dot material is coated on a side of the first lyophobic layer facing away from the first base substrate, which is convenient for spreading the quantum dots and beneficial for improving thickness uniformity of films formed by the quantum dots.

In specific implementation, when the photoluminescence layers include quantum dots, a contact angle of the quantum dots on the first lyophobic layer is greater than 90.

In some embodiments, the first lyophobic layer is, for example, an inorganic lyophobic layer. A material of the inorganic lyophobic layer may be silicon nitride or silicon oxide.

In some embodiments, a thickness of the first lyophobic layer is greater than or equal to 300 angstroms and less than or equal to 1500 angstroms.

Based on the same inventive concept, an embodiment of the present disclosure further provides a display panel, as shown in FIG. 12, including:
an array substrate 17;
the color film substrate 18 provided by an embodiment of the present disclosure and arranged opposite to the array substrate 17; the support portions are in contact with the array substrate 17;
a filling portion 19 located between the array substrate 17 and the color film substrate 18; and the filling portion 19 is partially filled in regions corresponding to the second opening regions 6.

The display panel according to the embodiment of the present disclosure includes the color film according to an embodiment of the present disclosure, since the color film substrate includes the support portions which can play a supporting role in a cell alignment processing, a supporting strength of the cell alignment processing can be ensured and thickness uniformity of the display panel obtained after the cell alignment processing can be ensured, even if a thickness of the filling portion between the color film substrate and the array substrate used in the cell alignment processing is reduced. In addition, since the color film substrate is provided with the dummy sub-pixel regions, and the first pixel definition layer includes the second opening regions corresponding to the dummy sub-pixel regions, the color film substrate and the array substrate are pressed in the cell alignment process, and excess filling portion may be squeezed to regions corresponding to the second opening regions to be stored, which can further reduce a minimum thickness of the filling portion formed by the filler between the color film substrate and the array substrate. Under the condition that the minimum thickness of the filling portion between the color film substrate and the array substrate is reduced, the distance between the photoluminescence layers and the light emitting devices in the array substrate is also reduced, thus avoiding the cross-color between adjacent photoluminescence layers.

It should be noted that FIG. 12 is illustrated by taking that the filling portion fills regions corresponding to the second opening regions as an example. Evidently, the filling portion also may not fill the regions corresponding to the second opening regions.

It should be noted that, in the related art, in the direction perpendicular to the first base substrate, the minimum thickness of the filling portion, that is, the minimum distance between the color film substrate and the array substrate, is about 30 microns to 50 microns. In the display panel according to the embodiment of the present application, since the support portions are provided, a thickness of a material coating for the filling portion can be reduced to 3 microns to 5 microns in a cell alignment process, and then the excess material of the filling portion is squeezed to the regions corresponding to the second opening regions by squeezing the material of the filling portion, so that in the direction perpendicular to the first base substrate, the minimum thickness of the filling portion, that is, the minimum distance between the color film substrate and the array substrate is less than 5 microns, and the distance between the photoluminescence layer and the light emitting devices can be effectively reduced. Under the condition that the support portions are uniformly distributed in the display area, the thickness uniformity of the display panel can be ensured.

In some embodiments, as shown in FIG. 12, the array substrate 17 includes:
a second base substrate 20;
a plurality of light emitting devices 21 which are located on a side of the second base substrate 20 facing the color film substrate 18 and are in one-to-one correspondence with the display sub-pixel regions;
a second encapsulation layer 22 located on a side of the light emitting devices 21 facing the color film substrate 18 and including an organic encapsulation structure 23; the organic encapsulation structure 23 includes a plurality of protrusion portions 24, and a surface of each protrusion portion 24 facing away from the second base substrate 20 is a spherical surface or an ellipsoidal surface; the protrusion portions 24 are in one-to-one correspondence with the light emitting devices 21, and an orthographic projection of the protrusion portions 24 on the second base substrate 20 covers an orthographic projection of the light emitting devices 21 on the second base substrate 20.

In the display panel according to the embodiment of the present disclosure, the second encapsulation layer includes the protrusion portions, and the protrusion portions are in one-to-one correspondence with the light emitting devices. The organic encapsulation structure including the protrusion portions can not only protects the light emitting devices from being eroded by water and oxygen, but also achieves a function of light convergence because surfaces of the protrusion portions facing away from the second base substrate are spherical or ellipsoidal, which is beneficial for improving a light emitting efficiency of a front side of the display panel. Herein, a light emitting direction of the front side is the direction perpendicular to the first base substrate.

In some embodiments, under the condition that the surface of each protrusion portion facing away from the second base substrate is a spherical surface or an ellipsoidal surface, a shape of the protrusion portion is a portion of a sphere or a portion of an ellipsoid. When the surface of the protrusion portion facing away from the second base substrate is a spherical surface, a volume of the protrusion portion is less than half of a volume of the corresponding complete sphere, and when the surface on the protrusion portion facing away from the second base substrate is an ellipsoidal surface, the volume of the protrusion portion is less than half of the corresponding complete ellipsoid.

In some embodiments, in a direction perpendicular to the second base substrate, a maximum thickness h3 of the protrusion portion is greater than or equal to 1 micron and less than or equal to 3 microns.

In some embodiments, the organic encapsulation structure 23 further includes an organic lyophobic layer 25;
the organic lyophobic layer 25 is provided as a whole layer between the organic encapsulation structure 23 and the second base substrate 20; or the organic lyophobic layer 25 includes a plurality of fifth opening regions 26, and the protrusion portions 24 are located in the fifth opening regions 26.

In the display panel according to the embodiment of the present disclosure, the organic encapsulation structure of the array substrate further includes the organic lyophobic layer, and when a material of the protrusion portions is printed on the organic lyophobic layer or printed within the fifth openings of the organic lyophobic layer, the material of the protrusion portions automatically shrinks to form the protrusion portions, which can simplify a preparation difficulty of the protrusion portions.

In some embodiments, a contact angle of the material of the protrusion portions on the organic lyophobic layer is greater than or equal to 30 degrees and less than or equal to 90 degrees.

In some embodiments, a thickness of the organic lyophobic layer is greater than or equal to 0.3 microns and less than or equal to 0.5 microns. A refractive index of the organic lyophobic layer is, for example, greater than or equal to 1.5 and less than or equal to 1.7.

In specific implementation, after the organic lyophobic layer is formed, the protrusion portions can be made by using, for example, a printing process or a pattern heating refluxing process.

In some embodiments, the light emitting devices are electroluminescent devices. The electroluminescent devices are, for example, organic light emitting diode devices (OLED). Optionally, the electroluminescent devices may be micro-size inorganic light emitting diode devices, such as micro light emitting diodes (Micro LED) or mini light emitting diodes (Mini LED).

Subsequently, description will be made by taking the light emitting devices being OLEDs as an example.

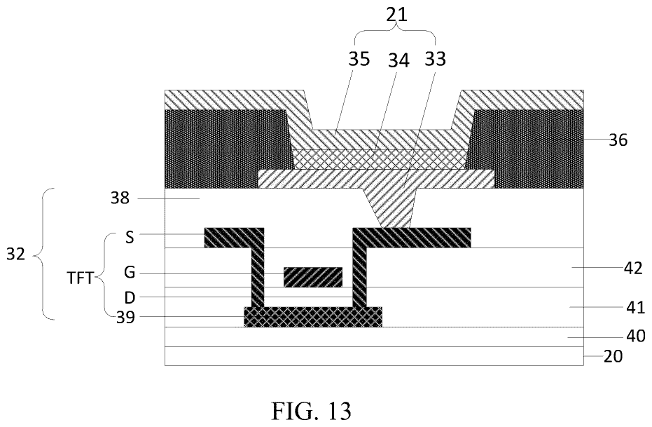

In some embodiments, as shown in FIG. 13, the array substrate 17 further includes a second pixel definition layer 36. The second pixel definition layer 36 includes a plurality of sixth opening regions 37, and the sixth opening regions 37 are in one-to-one correspondence with the display sub-pixel regions 2. Each light emitting device 21 includes an anode 33, a light emitting functional layer 34, and a cathode 35 sequentially stacked in a sixth opening region 37. The sixth opening region 37 exposes a region of a portion of the anode 33 and the second pixel definition layer 36 covers an edge of the anode 33. Cathodes 35 of a plurality of light emitting devices are integrally connected with each other.

In specific implementation, the light emitting functional layer includes an organic light emitting layer. Each light emitting device may include a single organic light emitting layer, and of course, the light emitting device may also include a plurality of organic light emitting layers arranged in a stacked manner. Taking the light emitting device being a blue light emitting device as an example, for example, three blue light emitting layers may be stacked, four blue light emitting layers may be stacked, or three blue light emitting layers and one green light emitting layer may be stacked. A light emitting wavelength of the blue light emitting device is, for example, greater than or equal to 430 nm and less than or equal to 470 nm. Evidently, a light emitting wavelength range of the blue light emitting device may be further narrowed to 440 nm or more and 460 nm or less, and specifically, the light emitting wavelength of the blue light emitting device is 450 nm, for example.

In specific implementation, the light emitting functional layer may further include an electron injection layer, an electron transport layer, a hole transport layer, a hole injection layer, and the like.

In some embodiments, as shown in FIG. 12, the second encapsulation layer 22 further includes a first inorganic encapsulation layer 14 located between the light emitting devices 21 and the organic encapsulation structure 23, and a second inorganic encapsulation layer 15 located on a side of the organic encapsulation structure 23 facing away from the light emitting devices 21.

In some embodiments, materials of the first inorganic encapsulation layer and the second inorganic encapsulation layer include, for example, one or a combination of the following: silicon nitride, silicon oxide, silicon carbonitride. The first inorganic encapsulation layer covers the light emitting devices, protects the light emitting devices, and plays a role in blocking water and oxygen. A thickness of the first inorganic encapsulation layer is, for example, greater than or equal to 100 nm and less than or equal to 1000 nm, and a refractive index of the first inorganic encapsulation layer is, for example, greater than or equal to 1.5 and less than or equal to 1.7. The second inorganic encapsulation layer can enhance a encapsulation effect, a thickness of the second inorganic encapsulation layer may be greater than or equal to 100 nm and less than or equal to 300 nm, for example, and the thickness of the second inorganic encapsulation layer for strengthening a encapsulation effect may be smaller than the thickness of the first inorganic encapsulation layer. In addition, due to the high surface energy of inorganic materials such as silicon nitride and silicon oxide, and a contact angle between the organic encapsulation structure and the second inorganic encapsulation layer, a wettability of the organic encapsulation layer and the second inorganic encapsulation layer can be increased.

In some embodiments, as shown in FIG. 12, the array substrate 17 further includes a drive circuit layer 32 between the second base substrate 20 and the light emitting devices 21.

In specific implementation, the drive circuit layer includes a plurality of pixel drive circuits arranged in an array. The pixel drive circuits are configured to drive the light emitting devices to emit light. As shown in FIG. 13, each pixel drive circuit includes a thin film transistor (TFT) and a storage capacitor (not shown). The thin film transistor (TFT) includes an active layer 39, a gate G, a source S, and a drain D. FIG. 13 is illustrated by taking that the thin film transistor (TFT) is in a top gate structure as an example, and evidently, the thin film transistor (TFT) may also be in a bottom gate structure or another structure. As shown in FIG. 13, the drive circuit layer 32 further includes a second buffer layer 40 between the second base substrate 20 and the active layer 39, a first gate insulation layer 41 between the active layer 39 and the gate G, an interlayer insulation layer 42 between the first gate insulation layer 41 and the source S as well as the drain D, and a first planarization layer 38 between the light emitting device 3 and the source S as well as the drain D. The anode 33 is connected to the drain D through a via hole penetrating the first planarization layer 38.

Based on the same inventive concept, an embodiment of the present disclosure further provides a display apparatus, including the display panel according to an embodiment of the present disclosure.

The display apparatus according to the embodiment of the present disclosure is: any product or component with a display function, such as a mobile phone, a tablet computer, a television, a display, a laptop computer, a digital photo frame, or a navigator, etc. Other essential components of the display apparatus should be understood to be included in the display apparatus by those of ordinary skills in the art, which will not be repeated here, and should not be taken as a limitation on the present disclosure. The implementation of the display apparatus may refer to the above embodiments of the color film substrate as well as the embodiments of the display panel, which will not be repeated.

To sum up, in the color film substrate, the display panel and the display apparatus according to the embodiments of the present disclosure, the color film substrate includes a plurality of support portions, and the support portions are arranged in a region outside the first opening regions, which will not affect the display. Since the distance between the surfaces of the support portions facing away from the first base substrate and the first base substrate is larger than the maximum value of the distance between the surface of the first encapsulation layer facing away from the first base substrate and the first base substrate, the support portions can play a supporting role in the cell alignment process, and even if a thickness of the filler between the color film substrate and the array substrate used in the cell alignment process is reduced, a supporting strength of the cell alignment process can be ensured and thickness uniformity of the display panel obtained after the cell alignment process can also be ensured. In addition, since the color film substrate is provided with the dummy sub-pixel regions, and the first pixel definition layer includes the second opening regions corresponding to the dummy sub-pixel regions, regions corresponding to the second opening regions do not need to perform displaying, so that a photoluminescence layer does not need to be provided. Therefore, the first encapsulation layer covers the second opening regions to form grooves. In the cell alignment process, the color film substrate and the array substrate are pressed, and the excess filler may be squeezed to the regions corresponding to the second opening regions to be stored, which can further reduce a minimum thickness of the filling portion formed by the filling material between the color film substrate and the array substrate. Under the condition that the minimum thickness of the filling portion between the color film substrate and the array substrate is reduced, the distance between the photoluminescence layers and the light emitting devices in the array substrate is also reduced, thus avoiding cross-color between adjacent photoluminescence layers.

Although preferred embodiments of the present disclosure have been described, those skilled in the art may make additional changes and modifications to these embodiments once basic inventive concepts are known. Therefore, the appended claims are intended to be interpreted to encompass preferred embodiments as well as all changes and modifications falling within the scope of the present disclosure.

Apparently, those skilled in the art may make various modifications and variations to the embodiments of the present disclosure without departing from the spirit and the scope of the embodiments of the present disclosure. Thus, if these modifications and variations to the embodiments of the present disclosure fall within the scope of the claims of the present disclosure and their equivalent techniques, the present disclosure is intended to include these modifications and variations.

1. A color film substrate, comprising:
a first base substrate, comprising a plurality of display sub-pixel regions and a plurality of dummy sub-pixel regions which are arranged in an array;
a first pixel definition layer located on a side of the first base substrate and comprising a plurality of first opening regions and a plurality of second opening regions; the first opening regions are in one-to-one correspondence with the display sub-pixel regions, and the second opening regions are in one-to-one correspondence with the dummy sub-pixel regions;
a plurality of photoluminescence layers located within at least a part of the first opening regions;
a first encapsulation layer located on a side of the first pixel definition layer and the photoluminescence layers facing away from the first base substrate; an orthographic projection of the first encapsulation layer on the first base substrate covers orthographic projections of the first pixel definition layer, the photoluminescence layers, the first opening regions and the second opening regions on the first base substrate; and
a plurality of support portions located on a side of the first encapsulation layer facing away from the first base substrate; an orthographic projection of the support portions on the first base substrate is not overlapped with an orthographic projection of the first opening regions on the first base substrate; and a distance between a surface of each support portion facing away from the first base substrate and the first base substrate is greater than a maximum value of a distance between a surface of the first encapsulation layer facing away from the first base substrate and the first base substrate.

2. The color film substrate according to claim 1, wherein a ratio of a quantity of the display sub-pixel regions to a quantity of the dummy sub-pixel regions is a positive integer;
the plurality of display sub-pixel regions and the plurality of dummy sub-pixel regions are arranged in an array along a first direction and a second direction, wherein the first direction intersects with the second direction; and
in the first direction and/or in the second direction, a quantity of display sub-pixel region(s) provided between any two adjacent dummy sub-pixel regions is the same.

3. The color film substrate according to claim 2, wherein a shape of an orthographic projection of a first opening region on the first base substrate is the same as a shape of an orthographic projection of a second opening region on the first base substrate, and an area of the orthographic projection of the first opening region on the first base substrate is substantially equal to an area of the orthographic projection of the second opening region on the first base substrate.

4. The color film substrate according to claim 2, wherein the plurality of display sub-pixel regions and the plurality of dummy sub-pixel regions are divided into a plurality of pixel regions; and each of the pixel regions comprises a plurality of the display sub-pixel regions and one of the dummy sub-pixel regions.

5. The color film substrate according to claim 4, wherein each of the pixel regions comprises three display sub-pixel regions and one dummy sub-pixel region, and the three display sub-pixel regions and the one dummy sub-pixel regions are arranged in a 2×2 array.

6. The color film substrate according to claim 1, wherein an area of an orthographic projection of a support portion on the first base substrate is smaller than an area of an orthographic projection of a second opening region on the first base substrate, and the orthographic projection of the support portion on the first base substrate falls within the orthographic projection of the second opening region on the first base substrate.

7. The color film substrate according to claim 6, wherein a center of the orthographic projection of the support portion on the first base substrate substantially coincides with a center of the orthographic projection of the second opening region on the first base substrate.

8. The color film substrate according to claim 6, wherein a quantity of the support portions is the same as a quantity of the second opening regions.

9. The color film substrate according to claim 1, wherein the orthographic projection of the support portions on the first base substrate falls within the orthographic projection of the first pixel definition layer on the first base substrate.

10. The color film substrate according to claim 9, wherein orthographic projections of a plurality of support portions surround an orthographic projection of a second opening region on the first base substrate.

11. The color film substrate according to claim 1, wherein in a direction from the first base substrate towards the support portions, an area of a cross section of each support portion parallel to the first base substrate is gradually reduced.

12. The color film substrate according to claim 11, wherein a ratio of an area of the surface of the support portion facing away from the first base substrate to an area of a surface of the support portion close to the first base substrate is greater than or equal to 0.6 and less than 1; or
an orthographic projection of the support portion on the first base substrate is circular.

13. (canceled)

14. The color film substrate according to claim 12, wherein a diameter of the surface of the support portion facing away from the first base substrate is greater than or equal to 3 microns and less than or equal to 10 microns.

15. The color film substrate according to claim 1, wherein the distance h1 between the surface of the support portion facing away from the first base substrate and the first base substrate, and the maximum value h2 of the distance between the surface of the first encapsulation layer facing away from the first base substrate and the first base substrate satisfy: 1 micron≥h1−h2≥3 microns.

16. The color film substrate according to claim 1, wherein further comprising:
a first light shielding layer located between the first pixel definition layer and the first base substrate and comprising a plurality of third opening regions and a plurality of fourth opening regions; the third opening regions are in one-to-one correspondence with the display sub-pixel regions, and the fourth opening regions are in one-to-one correspondence with the dummy sub-pixel regions; and
a plurality of color resists located within the third opening regions.

17. The color filter substrate according to claim 16, wherein further comprising:
a first lyophobic layer located between the color resists and the photoluminescence layers.

18. A display panel, comprising:
an array substrate;
the color film substrate according to claim 1, arranged opposite to the array substrate; the support portions are in contact with the array substrate;
a filling portion located between the array substrate and the color film substrate; and the filling portion is partially filled in regions corresponding to the second opening regions.

19. The display panel according to claim 18, wherein the array substrate further comprises:
a second base substrate;
a plurality of light emitting devices which are located on a side of the second base substrate facing the color film substrate and are in one-to-one correspondence with the display sub-pixel regions;
a second encapsulation layer located on a side of the light emitting devices facing the color film substrate and comprising an organic encapsulation structure; the organic encapsulation structure comprises a plurality of protrusion portions, and a surface of each protrusion portion facing away from the second base substrate is a spherical surface or an ellipsoidal surface; the protrusion portions are in one-to-one correspondence with the light emitting devices, and an orthographic projection of the protrusion portions on the second base substrate covers an orthographic projection of the light emitting devices on the second base substrate.

20. The display panel according to claim 19, wherein the organic encapsulation structure further comprises an organic lyophobic layer;
the organic lyophobic layer is arranged as a whole layer between the organic encapsulation structure and the second base substrate; or the organic lyophobic layer comprises a plurality of fifth opening regions, and the protrusion portions are located within the fifth opening regions.

21. A display apparatus, comprising the display panel according to claim 18.
